(19) United States
(12) Patent Application Publication
(10) Pub. No.: US 2010/0116689 A1
(43) Pub. Date: May 13, 2010

(54) Systems and Methods for Controlling Ion Deposition

(76) Inventors: Tom Greene, Morristown, TN (US); Richard Moyers, Morristown, TN (US)

Correspondence Address: Klemchuk Kubasta LLP, 8150 N Central Expressway, SUITE 1150, DALLAS, TX, 75206, US

(21) Appl. No.: 12/614,181

(22) Filed: Nov. 6, 2009

Related U.S. Application Data
(60) Provisional application No. 61/112,705, filed on Nov. 7, 2008.

(51) Int. Cl. C02F 1/461; G01R 27/08

(52) U.S. Cl. 205/743; 205/742; 205/759; 205/744; 204/229.8; 324/705

(57) ABSTRACT

The present disclosure generally provides systems and methods of controlling an ion concentration in water, for example, a silver ion concentration. The method of depositing ions in the water includes determining a conductivity level of the water using a reference probe. A power level based on the determined conductivity level is also determined. Power is applied to a deposition probe corresponding to the determined power level using a first electrical circuit, and a concentration of ions are deposited in the water.

### CROSS REFERENCE TO RELATED APPLICATION

This application claims benefit under 35 U.S.C. §119(e) of U.S. Provisional Patent Application Ser. No. 61/112,705 filed on Nov. 7, 2008 in the United States Patent and Trademark Office entitled “Method and Apparatus for Controlling Silver Ion Deposition.” The entire disclosure of U.S. Provisional Patent Application Ser. No. 61/112,705 is incorporated herein by reference as if fully disclosed.

### TECHNICAL FIELD

The present disclosure generally relates to a system and method for controlling an ion concentration, and more particularly controlling the concentration of silver ions that are released into the wash water of a laundry appliance.

### BACKGROUND

Silver is widely known for its antibacterial properties when used in a washer appliance. Silver ions may be trapped in fabric to provide ongoing protection against odor-causing bacteria. Previous known methods for releasing silver ions into wash water have been the use of electrolysis of metallic silver by means of a voltage or current source. This is typically implemented by positioning two parallel silver rods into the flow of water supplying the laundry appliance. An electrical potential is applied across the two rods causing an electrical current to pass between them thereby ionizing the silver particles on the surface of the rods. The ionized silver particles are then released into the water stream. The rods are typically sealed inline with the plumbing of the apparatus and should be replaced before they erode to the point of creating a path for water to leak outside the system.

The conductivity of the water affects the concentration of silver ions released into the water when a fixed voltage or fixed current is applied to the silver rods. Unfortunately, for many household environments, the conductivity of the water supplied to a washing appliance is not constant, and the total dissolved solids (“TDS”) can range anywhere from 30 parts per million (“ppm”) to over 800 ppm. In many cases, because of the variation of the conductivity and the total dissolved solids in the water, the silver ion concentration can range anywhere from a few parts per billion (“ppb”) to well over 300 ppb.

Thus, there exists a need for a system and method to ensure a relatively constant concentration of silver ions to be released into a flow of water regardless of the conductivity of the water used in the electrolysis process.

### SUMMARY

Embodiments of the present disclosure generally provide systems and methods of controlling an ion concentration in water, for example, a silver ion concentration. The method of depositing ions in the water includes determining a conductivity level of the water using a reference probe. A power level based on the determined conductivity level is also determined. Power is applied to a deposition probe corresponding to the determined power level using a first electrical circuit, and a concentration of ions are deposited in the water.

In one embodiment, the present disclosure could allow a relatively constant silver ion concentration to be released into a water stream regardless of the conductivity of the water used in the electrolysis that ionizes the silver on a deposition probe.

In one embodiment, the present disclosure could also allow a user to be notified if deposition rods used in the electrolysis have worn to a certain point. For example, a user may notified when deposition rods have worn past a mid-point, and also notified when the deposition rods have worn past a point when they may no longer be effective and should be replaced.

Other technical features may be readily apparent to one skilled in the art from the following figures, descriptions, and claims.

### BRIEF DESCRIPTION OF THE DRAWINGS

For a more complete understanding of this disclosure and its features, reference is now made to the following description, taken in conjunction with the accompanying drawings, in which:

FIG. 1 is a schematic of an ion deposition system coupled to a water source and a washer appliance according to one embodiment of the present disclosure;

FIGS. 2A-2C illustrate isometric views of the deposition probe of FIG. 1 at various stages of wear according to one embodiment of the present disclosure;

FIG. 3 illustrates a flow diagram of a method for controlling the concentration of ions deposited in water according to one embodiment of the present disclosure;

FIG. 4 illustrates a flow diagram of a method for determining and alerting a user of the wear level of the deposition probe of FIG. 1 according to one embodiment of the present disclosure; and

FIG. 5 illustrates a schematic of a circuit used to control the concentration of ions deposited in water according to one embodiment of the present disclosure.

### DETAILED DESCRIPTION

The present disclosure generally provides systems and methods for depositing ions in water supplied to a washer appliance, such as depositing silver ions into the water. According to the teaching of this disclosure, the ion concentration may be held generally constant regardless of the conductivity of the water or the wear of a deposition probe as a result of electrolysis. In certain embodiments, a silver ion concentration of approximately 20 parts per billion (“ppb”) may be a desired level to ensure that enough silver ions are deposited in the wash water to be effective, but not too many silver ions are deposited such that the effectiveness may be reduced.

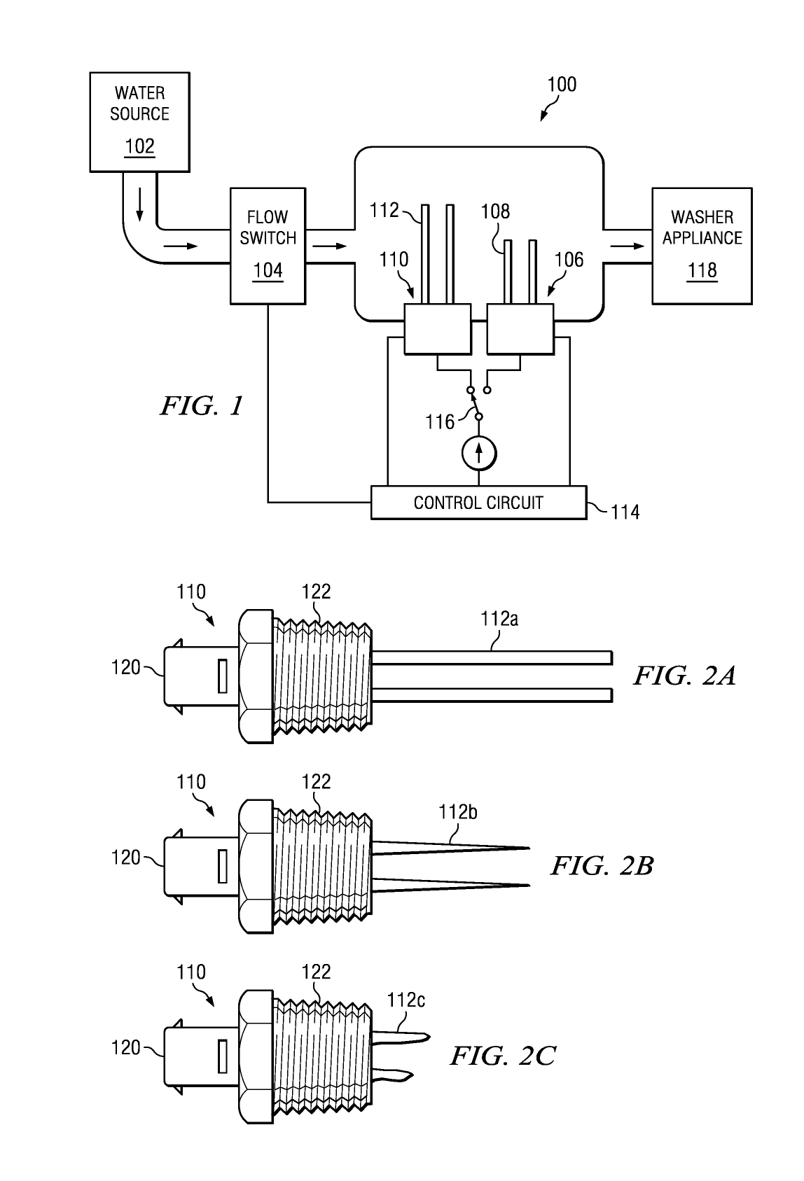

FIG. 1 generally illustrates a schematic of an embodiment of an ion deposition system 100 according to one embodiment of the present disclosure. It should be understood that system 100 shown in FIG. 1 is for illustrative purposes only and that any other suitable system or subsystem could be used in conjunction with or in lieu of system 100 according to one embodiment of the present disclosure. The ion deposition system 100 deposits metallic ions in water. For example, the ion deposition system may deposit silver ions in a flow of water demanded by a washer appliance 118. Silver ions may have beneficial properties in killing bacteria and cleaning laundry, in addition to, or in lieu of detergent.

The ion deposition system 100 receives water from a water source 102. The water source 102 may be a conventional cold water line that supplies water for use by the residential washer appliance 118. In a flow line with the water source 102 may be a flow switch 104. The flow switch 104 may communicate with a control circuit 114, which may determine if water is flowing through the ion deposition system 100 as a result of a demand from the washer appliance 118. If the control circuit 114 determines that water is flowing through ion deposition system 100, it may allow power to be supplied to the system 100. If the control circuit 114 determines that no water is flowing to the ion deposition system 100, it can shut off the power to the ion deposition system 100.

A pair of probes positioned in-line with the water flow may receive water flowing past flow switch 104. A reference probe 106 may provide information as to the conductivity of the water, and a deposition probe 110 may release silver ions in the water when it is subjected to electrolysis. The reference probe 106 may include a pair of reference rods 108. The reference rods 108 may be made of a non-corrosive metallic material, and the electrical resistance provided by the reference rods 108 may indicate a conductivity of the water. The conductivity of the water may depend on the concentration of total dissolved solids (“TDS”) in the water. Total dissolved solids may include inorganic salts, such as calcium, magnesium, potassium sodium, bicarbonates, chlorides, and sulfates. TDS may also include small amounts of organic matter that are dissolved in the water. Most of these substances are associated with the water's hardness and bitter taste. Their presence may also lead to corrosion or encrustation in water-distribution systems. In a household environment, the concentration of total dissolved solids may range from 30 parts per million (ppm) to 800 ppm. For example, tap water typically has a TDS concentration of approximately 70 ppm. When the concentration of total dissolved solids is high the water has a higher conductivity. In contrast, when the TDS level is lower, the water has a lower conductivity. Water with a higher conductivity will cause more silver ions to be released when the deposition probe 110 is subjected to electrolysis if the deposition probe 110 voltage is held constant. Thus, it is beneficial for the system 100 to cause a relatively constant number of silver ions to be released into the water regardless of the conductivity of the water. For example, a silver ion concentration of approximately 20 ppb may be desirable.

The deposition probe 110 may include deposition rods 112. The deposition rods 112 may be coated with or a solid metallic material that ionizes when subjected to electrolysis. For example, the deposition rods 112 may be coated with silver and release silver ions into the water when subjected to electrolysis. The current required to ionize the deposition rods 112 may come from a current source controlled by a control circuit 114. In certain embodiments, the current source may be a variable current source to allow different current levels to be supplied to the reference probe 106 or the deposition probe 110. The control circuit 114 may determine how much current or power to supply to either the deposition probe 110 or the reference probe 106. The control circuit 114 may also use a feedback voltage and a feedback current returned from the reference probe 106 to determine a reference probe resistance provided by the reference probe 106. This resistance may allow the control circuit 114 to determine the conductivity level of the water and use this determination in further calculations, such as the calculation of the current to be supplied to the deposition probe 110 to deliver the desired power level. Likewise, the control circuit 114 may also use a feedback voltage and a feedback current returned from the deposition probe 110 to determine the resistance of the deposition probe 110. This resistance determination may also be used in further calculations, such as in a calculation to determine the degradation or wear of deposition rods 112. The control circuit 114 may also reverse the polarity of a voltage across the deposition probe 110 after a predetermined time, such as ten seconds. This continuous reversal of the polarity may ensure that each of the deposition rods 112 degrade or wear evenly.

In certain embodiments, the ion deposition system 100 may also include a switch 116. When the switch 116 is in a first position making an electrical connection with the reference probe 106, current from the current source may be supplied to the reference probe 106. When the switch 116 is in a second position making an electrical connection to the deposition probe 110 (as shown in FIG. 1), current from the same current source may be supplied to the deposition probe 110 causing electrolysis of the deposition rods 112 and releasing silver ions into the water. Thus, according to the teachings of the present disclosure, the ion deposition system 100 may ensure that a constant concentration of silver ions is received by washer appliance 118 regardless of the conductivity of the water or the wear of the deposition rods 112.

FIGS. 2A-2C generally illustrate embodiments of the deposition probe 110. It should be understood that the deposition probe 110 shown in FIGS. 2A-2C is for illustrative purposes only and that any other suitable system or subsystem could be used in conjunction with or in lieu of deposition probe 110 according to one embodiment of the present disclosure. The deposition probe 110 may include a threaded portion 122 to allow the deposition probe 110 to be inserted into the water flow with a watertight seal. The threaded portion 122 may also allow the deposition probe 110 to be easily unscrewed for removal and replacement. The deposition probe 110 may also include an electrical connection 120. The electrical connection 120 may allow deposition probe 110 to be connected to the current source and the control circuit 114.

The deposition probe 110 includes deposition rods 112. In certain embodiments, the deposition rods 112 may be a set of plates or tubes or any other configuration of material that will allow electrolysis and ionization of material on deposition rods 112. FIGS. 2A-2C illustrate the deposition rods 112 at increasing stages of degradation or wear. The deposition rods 112a shown in FIG. 2A may be that of a new deposition probe 110. The deposition rods 112a may have a length of approximately 2.75 inches. FIG. 2B illustrates an aged deposition probe 110 with aged deposition rods 112b. The deposition rods 112b may be shorter and have less mass than deposition rods 112a because they have been subjected to a certain period of use and have been subjected to numerous events of electrolysis causing the material of the deposition rods 112a to be released into the water supplying the washer appliance 118. For example, deposition rods 112b may be 1.8 inches long. Similarly, deposition rods 112c may be even shorter and have less mass than deposition rods 112b because they have been subjected to an even longer period of use and even more events of electrolysis. The length of deposition rods 112c may be a half of an inch. When deposition rods 112c wear to approximately a half of an inch, they may need to be replaced to ensure proper operation of ion deposition system 100 in accordance with the teachings of the present disclosure.

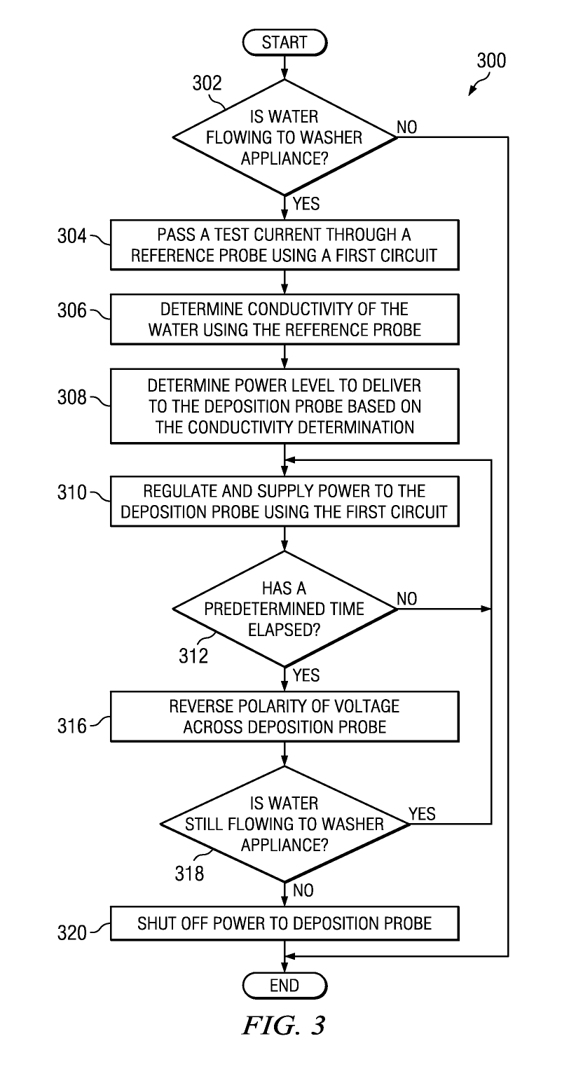

FIG. 3 is a somewhat simplified flow diagram illustrating method 300 of controlling the concentration of silver ions deposited in a flow of water supplying a washer appliance 118. It should be understood that method 300 shown in FIG. 3 is for illustrative purposes only and that any other suitable method or sub-method could be used in conjunction with or in lieu of method 300 according to one embodiment of the present disclosure. It should also be understood that the steps of method 300 could be performed in any suitable order or manner.

The method 300 begins at step 302 where it is determined if water is flowing to the washer appliance 118. This determination may be made by the control circuit 114 via input from the flow switch 104, which determines if water is flowing through the ion deposition system 100. If no water is flowing, then the method ends, as there is no water to release silver ions into. If the water is flowing, at step 304 a momentary test current is passed through the reference probe 106 using a first current source that is part of a first electrical circuit. Next, at step 306 a conductivity level of the water is determined by using the reference probe. The conductivity level may correspond to a concentration of total dissolved solids in the water received from the source. The test current may cause a feedback voltage and a feedback current to be returned to the control circuit 114. Using this feedback voltage and feedback current, the control circuit 114 may determine a resistance caused by the reference probe 106. This resistance may be used to determine the conductivity of the water.

At step 308, a level of power to deliver to the deposition probe 110 may be determined based on the determination of the conductivity of the water. If a high conductivity of the water is determined then the power supplied to the deposition probe may be lower to keep the concentration of silver ions in the water relatively constant. Thus, there may be an inverse relationship of power to the deposition probe 110 to the conductivity of the water. At step 310, the power level determined at step 308 may be regulated and supplied to the deposition probe 110. This power may be delivered by the same source that supplied the test current to the reference probe in step 304.

At step 312, it may be determined whether a predetermined time has elapsed. In certain embodiments, it may be determined if 10 seconds has elapsed. If 10 seconds has not elapsed then the polarity of the voltage across the deposition probe 110 is not changed and the method returns to step 310. If the predetermined time has elapsed, then the polarity of the voltage across the deposition probe 110 is reversed at step 316. This reversal allows the two deposition rods 112 to release ions at an even rate. Thus, each deposition rod 112 will wear approximately evenly.

It is determined whether the water is still flowing to the washer appliance 118 at step 318. If the water is still flowing, then the method 300 returns to step 310 and power continues to be supplied to the deposition probe 110. If the water is not still flowing, then the power to the deposition probe 110 is shut off at step 320 and the method ends.

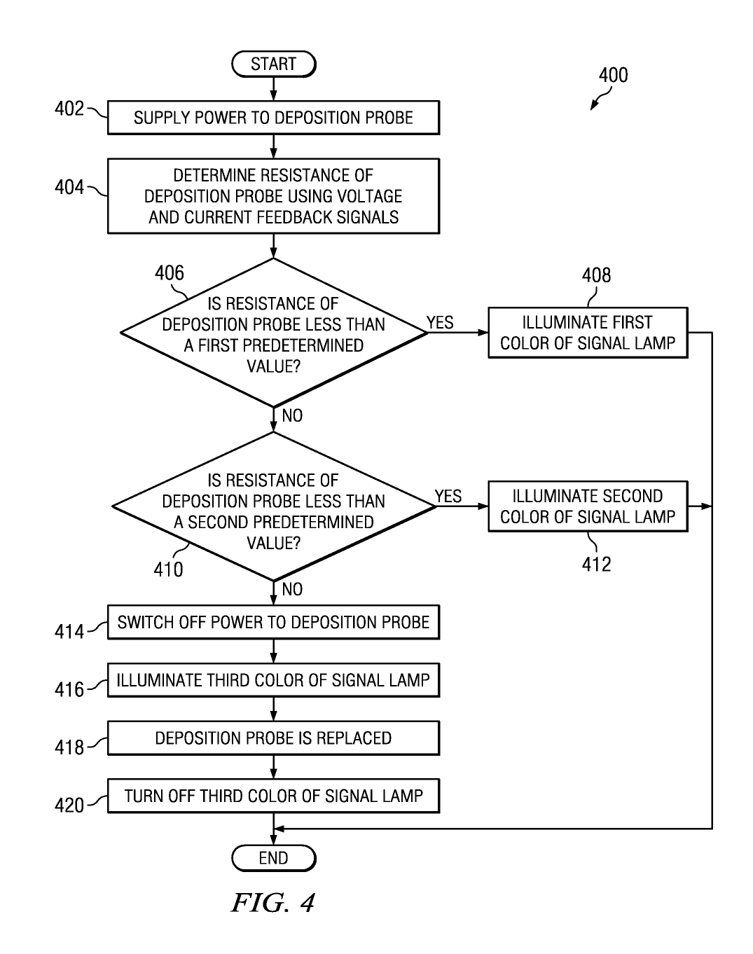

FIG. 4 is a somewhat simplified flow diagram illustrating a method 400 of determining the wear of the deposition rods 112 in accordance with one embodiment of the present disclosure. It should be understood that method 400 shown in FIG. 4 is for illustrative purposes only and that any other suitable method or sub-method could be used in conjunction with or in lieu of method 400 according to one embodiment of the present disclosure. It should also be understood that the steps of method 400 could be performed in any suitable order or manner.

The method 400 begins at step 402 when power is supplied to the deposition probe 110. Once the power is supplied to the deposition probe 110, a feedback voltage and feedback current may be used by the control circuit 114 to determine a resistance of the deposition probe 110. In certain embodiments, a feedback voltage and feedback current received from the reference probe 106 may be used to determine a resistance of the reference probe 106. This resistance may be used as a baseline resistance that takes into account the conductivity of the water in the determination. The reference probe 106 resistance may be used to calculate a first and a second predetermined value and compared to the deposition probe 110 resistance, which also may be dependent on the conductivity level of the water.

At step 406, it is determined if the resistance of the deposition probe 110 is less than a first predetermined value. For example, in an embodiment where the conductivity level of the water corresponds to approximately 500 ppm, a resistance of approximately 185 ohms may be determined. This resistance may be less than a predetermined value of approximately 400 ohms, which may indicate that the deposition rod 112 length is greater than 1.8 inches, and therefore the deposition probe 110 is not in need of replacement. Thus, if the resistance is less than a first predetermined value, a first color of a signal lamp may be illuminated at step 408, which may indicate to the user that the deposition probe 110 is in an optimal operating condition because it still has sufficient material to release ions into the water.

If the deposition probe 110 resistance is not less than a predetermined value, then the method proceeds to step 410. At step 410, it is determined if the deposition probe 110 resistance is less than a second predetermined value. If the resistance of the deposition probe 110 is less than the second predetermined value, but greater than the first predetermined value, then a second color of a signal lamp may be illuminated at step 412. This second color may signal to the user that the deposition rods 112 have worn past their optimum length and can be subjected to more electrolysis, but the deposition probe 110 may soon need to be replaced. For example, the deposition probe 110 resistance of approximately 500 ohms may be determined. This may be less than the predetermined value of 850 ohms, and may correspond to a length of deposition rods 112 that is less than 1.8 inches but greater than 0.5 inches.

If the deposition probe 110 resistance is not less than the second predetermined value, then the method proceeds to step 414. At step 414, power to the deposition probe 110 may be switched off, and a third color of the signal lamp may be illuminated at step 416. It should be understood that this disclosure is not limited to only illuminating a signal lamp to convey a message regarding the length and wear of deposition rods 112 to the user, and any display that can convey a message to a user may be used in accordance with the present disclosure. For example, in certain embodiments, a screen may display a verbal message to the user. The illumination of the third color of the signal lamp at step 416 and shutting off the power to the deposition probe 110 may result when deposition rods 112 are less than 0.5 inches long. Deposition rods 112 that are less than 0.5 inches long may be in need of immediate replacement because there may not be sufficient material on the deposition rods 112 to allow sufficient electrolysis according to the teaching of the present disclosure. Furthermore, power may be shut off to the deposition probe 110 to eliminate any chance that the user is able to continue to operate the system 100 when the length of the deposition rods 112 are so short. In certain embodiments, the deposition probe 110 may be replaced at step 418, causing the third signal lamp to be turned off at step 420, where the method ends.

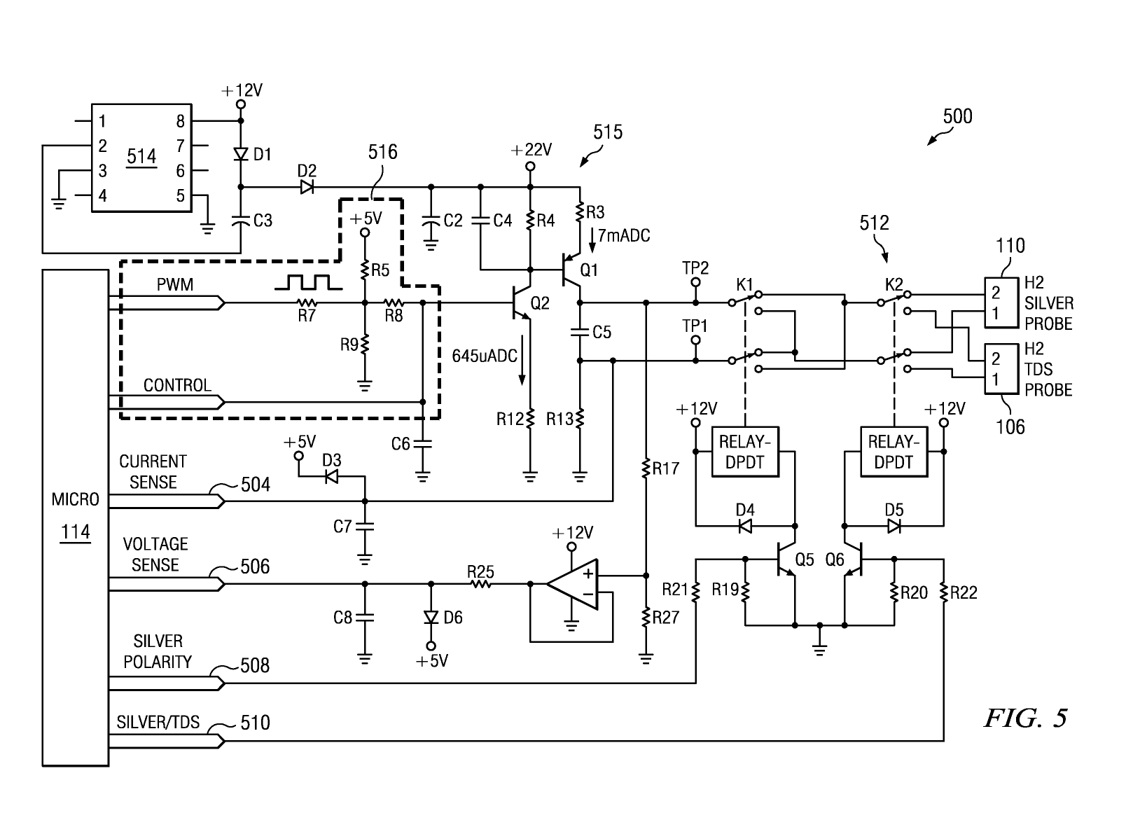

FIG. 5 shows a schematic of a circuit 500 for controlling the concentration of ions released in water as a result of electrolysis of the deposition probe 110 in accordance with the teachings of the present disclosure. Among other components, the circuit 500 may be comprised of the control circuit 114, the deposition probe 110 (labeled H2 Silver Probe in FIG. 5), and the reference probe 106 (labeled H2 TDS Probe in FIG. 5).

Control circuit 114 may be a microcontroller circuit. It may operate as a part of a closed loop system with the surrounding circuits to function primarily as a precision low power regulator to deposition probe 110, where the deposition probe 110 power can range from 5-30 mW depending on the conductivity of the water. Regulation may be achieved by controlling a current source circuit 515 with a 10-bit high-resolution pulse width modulation circuit 516. Inputs from polarity circuit 508 and deposition/reference circuit 510 may be processed by control circuit 114 to calculate the differential voltage across deposition rods 112 and reference rods 108, as well as the respective reference or deposition probe current. These calculations may be further processed to determine power and resistance used for determining the condition of deposition rods 112, the water conductivity, and the appropriate power for deposition rods 112 to release the desired amount of silver ions into the water stream.

Control circuit 114 may be coupled to a current sensor circuit 504, a voltage sensor circuit 506, a polarity circuit 508, and a deposition/reference probe circuit 510. The current sensor circuit 504 may receive a feedback current from the deposition probe 110 or the reference probe 106. Similarly, the voltage sensor circuit 506 may receive a feedback voltage from deposition probe 110 or reference probe 106. Polarity circuit 508 may control switching the polarity of the voltage across the deposition probe 110. The deposition/reference probe circuit 510 may be coupled to the deposition probe 110 and the reference probe 106 and may control the routing of power to each. The circuit 500 may also include a switching circuit 512. This switching circuit 512 may generally correspond to switch 116 shown in FIG. 1. In the example embodiment shown, switching circuit 512 is a double pole, double throw switch, which allows the same power source to supply deposition probe 110 or reference probe 106. Circuit 500 also includes a power booster circuit 514. The power booster circuit 514 may be an integrated circuit that increases a 12-volt supply to a 22-volt supply. In certain embodiments, power booster circuit 514 may be a dedicated analog device.

It may be advantageous to set forth definitions of certain words and phrases used in this patent document. The term “couple” and its derivatives refer to any direct or indirect communication between two or more elements, whether or not those elements are in physical contact with one another. The terms “include” and “comprise,” as well as derivatives thereof, mean inclusion without limitation. The term “or” is inclusive, meaning and/or. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like.

While this disclosure has described certain embodiments and generally associated methods, alterations, and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method of depositing ions in water, comprising:
determining a conductivity level of the water using a reference probe;
determining a power level based on the determined conductivity level;
applying power to a deposition probe corresponding to the determined power level using a first electrical circuit; and
depositing a concentration of ions in the water.

2. The method of claim 1 further comprising:
ionizing a silver coating associated with the deposition probe, wherein the ionizing results in depositing a concentration of silver ions in the water.

3. The method of claim 2, further comprising maintaining the concentration of silver ions in the water regardless of the determined conductivity level of the water.

4. The method of claim 2 further comprising maintaining the concentration of silver ions in the water regardless of a length of the deposition probe.

5. The method of claim 1, wherein determining the conductivity level of the water further comprises:
passing a test current through the reference probe using the electrical circuit;
determining a reference probe resistance based on a reference probe feedback voltage and a reference probe feedback current to the electrical circuit; and
determining the conductivity level based on the reference probe resistance.

6. The method of claim 5 further comprising:
determining a deposition probe resistance based on a deposition probe feedback voltage and a deposition probe feedback current to the electrical circuit; and
comparing the reference probe resistance to the deposition probe resistance to determine a wear level of the deposition probe.

7. The method of claim 1 further comprising:
reversing a polarity of a voltage across the deposition probe when a predetermined time has elapsed.

8. The method of claim 1 further comprising:
determining that a water flow is present, the water flow resulting from a demand from a washing appliance.

9. The method of claim 8, further comprising:
switching off the current to the deposition probe when the water flow is not present.

10. A system for depositing ions in water, comprising:
a reference probe coupled to an electrical circuit;
a deposition probe coupled to the electrical circuit; and
wherein the electrical circuit comprises a power source, the electrical circuit being operable to:
determine a conductivity level of the water using the reference probe;
determine a power level to deliver to the deposition probe based on the determined conductivity level; and
supply the determined power level to the deposition probe, the power and the water ionizing a material on the deposition probe.

11. The system of claim 10, wherein the electrical circuit further comprises:
a switch having a first position and a second position; and
wherein when the switch is in the first position a reference probe current supplies the reference probe, and when the switch is in the second position, the deposition probe current supplies the deposition probe.

12. The system of claim 10, wherein the reference probe comprises a non-corrosive metallic material.

13. The system of claim 10, wherein the deposition probe comprises a silver coating.

14. The system of claim 10 further comprising:
a flow switch, the flow switch operable to detect a water flow resulting from a demand from a washer appliance, the flow switch further operable to activate the electrical circuit when the water flow is detected.

15. A method of determining wear of a deposition probe, comprising:
determining a deposition probe resistance based on a deposition probe feedback voltage and a deposition probe feedback current to an electrical circuit;
determining if the deposition probe resistance is less than a first predetermined value; and
indicating that the deposition probe has not worn past a first length when the deposition probe resistance is less than the first predetermined value.

16. The method of claim 15 further comprising:
determining if the deposition probe resistance is less than a second predetermined value, the second predetermined value being greater than the first predetermined value;
indicating that the deposition probe has worn past the first length when the deposition probe resistance is less than the second predetermined value but greater than the first predetermined value; and
indicating that the deposition probe has worn past a second length when the deposition probe resistance is greater than the second predetermined value, the second length being less than the first length.

17. The method of claim 16 further comprising:
shutting off a power to the deposition probe when the deposition probe resistance is greater than the second predetermined value.

18. The method of claim 16, wherein:
indicating that the deposition probe has not worn past the first length comprises displaying a first color;
indicating that the deposition probe has worn past the first length comprises displaying a second color; and
indicating that the deposition probe has worn past the second length comprises displaying a third color.

19. The method of claim 16, further comprising:
replacing the deposition probe with a new deposition probe; and
indicating that the new deposition probe has not worn past the first length.
